(19) United States
(12) Patent Application Publication
(10) Pub. No.: US 2013/0016298 A1
(43) Pub. Date: Jan. 17, 2013

(54) LIQUID CRYSTAL DISPLAY DEVICE AND METHOD OF MANUFACTURING THE SAME

(71) Applicants: Yasuharu SHINOKAWA, Osaka (JP); Eiichi Satoh, Osaka (JP)

(72) Inventors: Yasuharu SHINOKAWA, Osaka (JP); Eiichi Satoh, Osaka (JP)

(73) Assignee: Panasonic Corporation, Osaka (JP)

(21) Appl. No.: 13/619,822

(22) Filed: Sep. 14, 2012

Related U.S. Application Data
(63) Continuation of application No. PCT/JP2012/001588, filed on Mar. 8, 2012.

(30) Foreign Application Priority Data
Jul. 13, 2011 (JP) 2011-154530

(51) Int. Cl. G02F 1/1368; H01L 33/08

(52) U.S. Cl. 349/47; 438/30; 257/E33.053

(57) ABSTRACT

A liquid crystal display device includes a pair of transparent substrates disposed facing each other through a liquid crystal layer; a gate insulating film formed so as to cover a gate electrode formed in the pixel regions of one of the pair of the transparent substrates closer to the liquid crystal layer; a switching element made of a thin-film transistor placed on the gate insulating film; a first electrode placed on the switching element through first and second insulating films; and a second electrode placed on the first electrode through a third insulating film. The liquid crystal display device generates an electric field in parallel with the pair of the transparent substrates and between the first and second electrodes. The second insulating film is formed of an SOG material having Si—O bonds.

### TECHNICAL FIELD

The present invention relates to a liquid crystal display device, particularly to one based on a technology called IPS (in-plane switching), and to a method of manufacturing the devices.

### BACKGROUND ART

A liquid crystal display device based on a technology called IPS has a pair of transparent substrates disposed facing each other through a liquid crystal. Each pixel region of one of the transparent substrates closer to the liquid crystal has a pixel electrode; and a common electrode for generating an electric field (lateral electric field) parallel to the transparent substrates, between the pixel electrode and the common electrode. The amount of light transmitting through a region between the pixel electrode and the common electrode is regulated by controlling driving of the liquid crystal according to an electric field. Such a liquid crystal display device is known as being capable of providing unchanged display images even if viewed from a diagonal direction with respect to the screen surface (excellent in so-called wide viewing angle characteristics).

Conventionally, in such a liquid crystal display device, a pixel electrode and a common electrode have been formed of a conductive layer that does not transmit light. In recent years, however, the following type has been known. That is, common electrodes made of transparent electrodes are formed on the entire area of the region excluding around the pixel regions, and strip-shaped pixel electrodes are formed on the common electrodes through an insulating film.

With a liquid crystal display device thus structured, a lateral electric field is generated between a pixel electrode and a common electrode, which provides excellent wide viewing angle characteristics and a higher aperture ratio (refer to patent literature 1 for example).

Meanwhile, a liquid crystal display device based on the diagonal electric field method has been developed. In the device, pixel electrodes and common electrodes for applying an electric field to the liquid crystal layer are disposed on different layers through an insulating film. The device provides a wider viewing angle and a higher contrast than that based on the IPS method, and further the device can be driven at low voltage and has a high transmittance, thereby featuring bright display.

However, the device involves the following problems. That is, the potential difference between a drain signal line and a pixel electrode causes orientation misalignment, which produces a region that does not contribute to display near a signal line to decrease the aperture ratio. Further, coupling capacitance produced between a signal line and a pixel electrode is likely to degrade display quality (e.g. crosstalk).

Hence, a liquid crystal display device is devised in which pixel electrodes and common electrodes are disposed on an interlayer resin film in order to reduce such influence by potential of a signal line (refer to patent literatures 2 and 3 for example).

However, a request has been made for providing a liquid crystal display device with a higher aperture ratio (transmittance) and a method of manufacturing the device at low cost.

### CITATION LIST

### Patent Literature

PTL 1 Japanese Patent Unexamined Publication No. H11-202356
PTL 2 Japanese Patent Unexamined Publication No. 2009-122299
PTL 3 Japanese Patent Unexamined Publication No. 2010-145449

### SUMMARY OF THE INVENTION

A liquid crystal display device of the present invention includes a pair of transparent substrates; a gate insulating film; a switching element; a first electrode; and a second electrode. The pair of the transparent substrates is disposed facing each other through a liquid crystal layer. The gate insulating film is formed so as to cover the gate electrode formed in the pixel regions of one of the pair of the transparent substrates closer to the liquid crystal layer. The switching element is formed of a thin-film transistor provided on the gate insulating film. The first electrode is provided on the switching element through an insulating film. The second electrode is provided on the first electrode through an insulating film. The liquid crystal display device generates an electric field in parallel with the pair of the transparent substrates and between the first and second electrodes. The insulating film provided on the switching element is formed of an SOG (spin on glass) material having Si—O bonds.

A method of manufacturing a liquid crystal display device, of the present invention is one manufacturing a device that includes a pair of transparent substrates, a gate insulating film, a switching element, a first electrode, and a second electrode, and that generates an electric field parallel with the pair of transparent substrates between the first and second electrodes.

The pair of the transparent substrates of the liquid crystal display device is disposed facing each other through a liquid crystal layer. The gate insulating film is formed so as to cover a gate electrode formed in the pixel regions of one of the pair of the transparent substrates closer to the liquid crystal layer. The switching element is formed of a thin-film transistor provided on the gate insulating film. The first electrode is provided on the switching element through an insulating film. The second electrode is provided on the first electrode through an insulating film. The liquid crystal display device generates an electric field in parallel with the pair of the transparent substrates and between the first and second electrodes.

The method of manufacturing liquid crystal display devices is as follows. After an insulating film made of an SOG material having Si—O bonds is formed on a switching element, a first electrode is patterned on the insulating film. Then after an insulating film is formed on the first electrode, the contact hole is collectively formed in a plurality of the insulating films to expose part of the electrode of the switching element outside, and then the electrode of the switching element is connected to the second electrode.

As described above, the present invention allows providing a liquid crystal display device with a high aperture ratio (transmittance) and low cost.

### BRIEF DESCRIPTION OF DRAWINGS

FIG. 1 is a plan view showing the structure of the substantial part for one pixel, of a liquid crystal display device according to an embodiment of the present invention.

FIG. 2 is an outline sectional view of the switching element in FIG. 1, taken along line 2-2.

FIG. 3 is an outline sectional view of the liquid crystal layer in FIG. 1, taken along line 3-3.

FIG. 4A is a sectional view showing an example manufacturing process in a method of manufacturing liquid crystal display devices, according to the embodiment of the present invention.

FIG. 4B is a sectional view showing an example manufacturing process in the method of manufacturing liquid crystal display devices, according to the embodiment of the present invention.

FIG. 4C is a sectional view showing an example manufacturing process in the method of manufacturing liquid crystal display devices, according to the embodiment of the present invention.

FIG. 4D is a sectional view showing an example manufacturing process in the method of manufacturing liquid crystal display devices, according to the embodiment of the present invention.

FIG. 4E is a sectional view showing an example manufacturing process in the method of manufacturing liquid crystal display devices, according to the embodiment of the present invention.

### DESCRIPTION OF EMBODIMENT

### Exemplary Embodiment

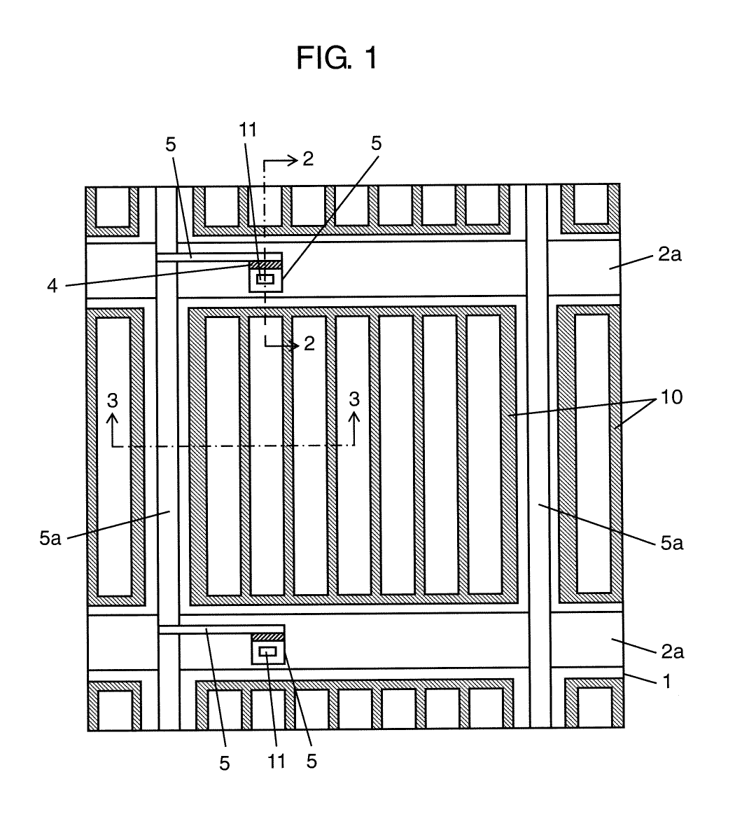

Hereinafter, a description is made of a liquid crystal display device and a method of manufacturing the device according to an embodiment of the present invention using FIGS. 1 through 4E.

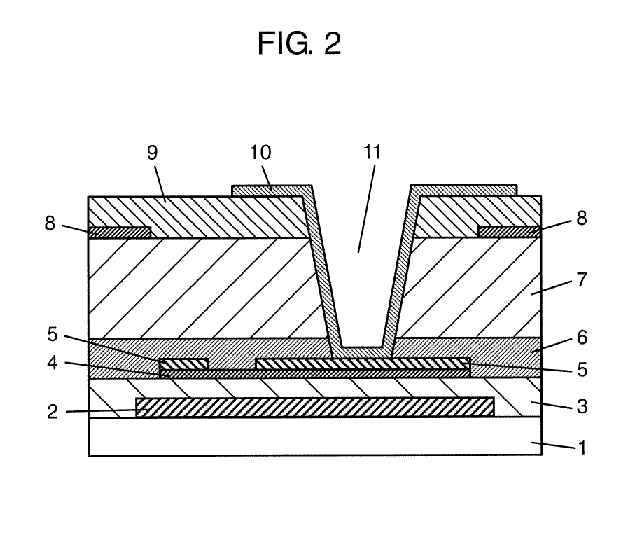

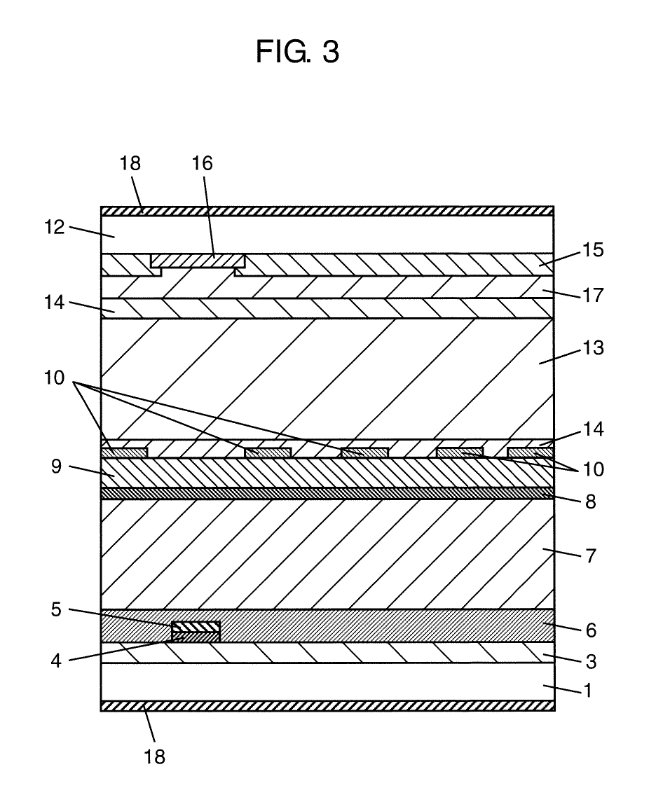

FIG. 1 is a plan view showing the structure of the substantial part for one pixel, of a liquid crystal display device according to an embodiment of the present invention. FIG. 2 is an outline sectional view of the switching element in FIG. 1, taken along line 2-2. FIG. 3 is an outline sectional view of the liquid crystal layer in FIG. 1, taken along line 3-3. The liquid crystal display device shown in the figures is of an active matrix type, where a plurality of pixels is arranged in a matrix.

As shown in FIGS. 1, 2, and 3, a pair of transparent substrates 1 and transparent substrate 12 is disposed facing each other through liquid crystal layer 13. A plurality of gate electrodes 2 is formed in the pixel regions of insulating transparent substrate 1 (e.g. a glass substrate) closer to liquid crystal layer 13, directly or through a base layer in a given pattern, and gate insulating film 3 is formed on transparent substrate 1 so as to cover gate electrode 2. Gate insulating film 3 has semiconductor film 4 formed thereon. Source/drain electrode 5 is formed on semiconductor film 4 to form a thin-film transistor as a switching element.

Here, semiconductor film 4 is desirably formed of an amorphous oxide semiconductor of InGaZnOₓ including In—Ga—Zn—O. To form a film of the amorphous oxide semiconductor, vapor phase deposition such as sputtering and laser deposition can be used with a polycrystalline sintered body having a composition of InGaO₃(ZnO)₄ for example as a target.

Gate electrode 2 and source/drain electrode 5 are connected to signal lines 2a and 5a, respectively, and the respective signal lines are formed so as to cross each other isolated by gate insulating film 3. Gate electrode 2 is formed integrally with signal line 2a that becomes a scanning signal line. Part of signal line 5a of source/drain electrode 5 combines as a video signal line, where both lines are connected to each other. Here, gate electrode 2, source/drain electrode 5, and signal lines 2a and 5a are formed of a single metal of Al, Mo, Cr, W, Ti, Pb, Cu, or Si; of a composite lamination (e.g. Ti/Al) of some of these metals ; or of a metal compound layer (e.g. MoW, AlCu). In this embodiment, gate electrode 2 and source/drain electrode 5 are formed of Cr; alternatively, they may be formed of different materials.

On source/drain electrode 5 (i.e. a switching element), first insulating film 6, second insulating film 7, first electrode 8 as a common electrode, third insulating film 9, and second electrode 10 as a pixel electrode are successively laminated. In other words, first electrode 8 is provided on the switching element through first insulating film 6 and second insulating film 7 as insulating films. Second electrode 10 is provided on first electrode 8 through third insulating film 9 as an insulating film. Second electrode 10 is connected to source/drain electrode 5 (i.e. a thin-film transistor) through contact hole 11 collectively formed in the three-layered films: first insulating film 6, second insulating film 7, and third insulating film 9. The wall surface of contact hole 11 is covered with second electrode 10.

First electrode 8 and second electrode 10 are formed of a transparent conductive film such as ITO (indium tin oxide). First electrode 8 is supplied with a common potential that is different from a potential applied to second electrode 10. Hence, first electrode 8, second electrode 10, and third insulating film 9 form a retention capacitor that is in addition transparent, thereby increasing the aperture ratio during transmission display.

Here, third insulating film 9 is ideally a silicon nitride film formed by plasma CVD (chemical vapor deposition). A silicon nitride film has a dielectric constant higher than a coated insulating film made of an organic or inorganic material, and than a silicon oxide film, thereby increasing the retention capacitance. Third insulating film 9 is desirably made closely packed by being formed at high temperature.

Second insulating film 7 is a coated insulating film made of an organic or inorganic material that is an SOG material having Si—O bonds. As described later, using an SOG material for second insulating film 7 allows using collective dry etching of first insulating film 6 and third insulating film 9, thereby simplifying the manufacturing process. Further, film formation can be made by a common coater, which reduces the film forming cost itself compared to an inorganic insulating film such as first insulating film 6 and third insulating film 9 formed by a vacuum device. Further, a film thicker than an inorganic insulating film can be easily formed, thereby increasing flatness and reducing parasitic capacitance. Second insulating film 7 is formed of an SOG material having Si—O bonds, which has a heat resistance high enough to form third insulating film 9 at 240° C. or higher, thereby forming more reliable third insulating film 9.

As shown in FIG. 3, at the side for displaying images, insulating transparent substrate 12 as the common substrate, made of such as a glass substrate is disposed so as to face transparent substrate 1, and liquid crystal layer 13 is disposed between transparent substrate 1 and transparent substrate 12. Second electrode 10, which becomes a surface for contacting liquid crystal layer 13 of transparent substrate 1, has oriented film 14 formed thereon. At the side for contacting liquid crystal layer 13 of transparent substrate 12, oriented film 14 is disposed as well. The inner surface where oriented film 14 of transparent substrate 12 is formed has color filter 15 and black matrix 16 formed thereon. Then, overcoat 17 is formed so as to cover color filter 15 and black matrix 16, and oriented film 14 is formed on overcoat 17.

The outer surfaces of transparent substrate 1 and transparent substrate 12 have polarizing plate 18 disposed thereon. In FIG. 1, polarizing plate 18 is not shown. Further, such as a phase difference plate may be disposed on at least one of transparent substrate 1 and transparent substrate 12 as required.

Here, in a liquid crystal display device according to the embodiment, second electrode 10 has a linear part and is formed in a comb-teeth shape. First electrode 8 is formed in a sheet shape. Then, the liquid crystal display device generates an electric field in parallel with transparent substrate 1 and transparent substrate 12 between second electrode 10 and first electrode 8 to drive liquid crystal layer 13 for displaying.

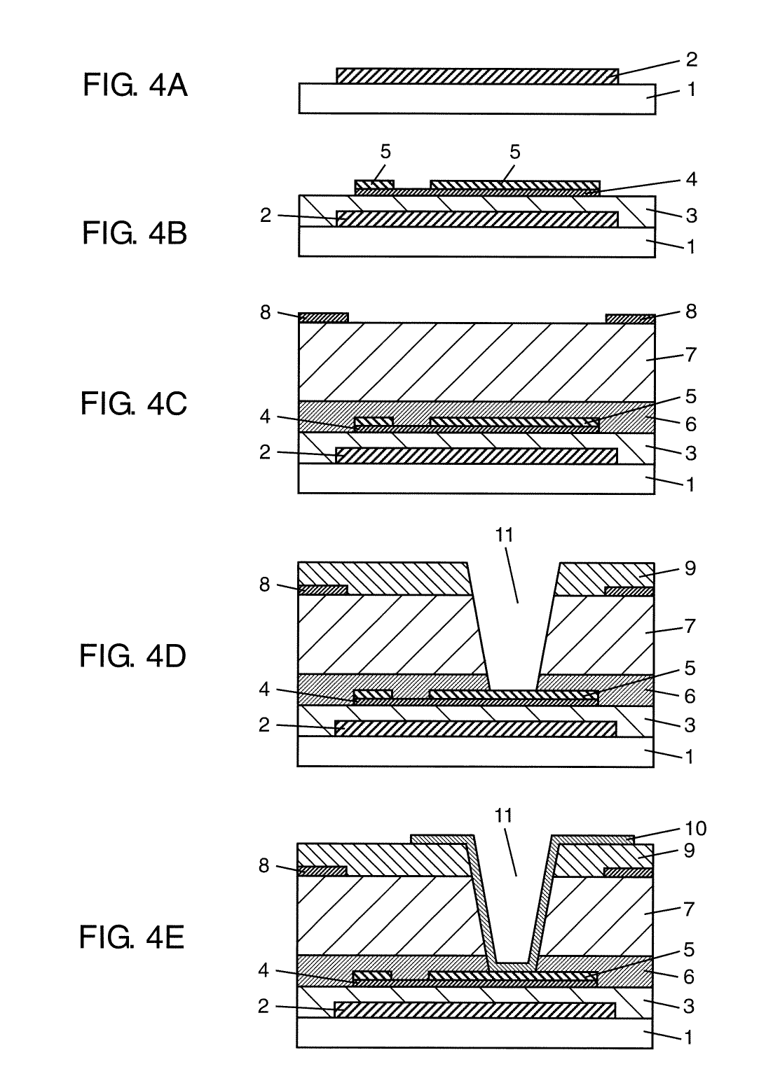

Next, a description is made of an example method of manufacturing liquid crystal display devices, according to an embodiment of the present invention using FIGS. 4A through 4E. FIGS. 4A through 4E are sectional views showing an example manufacturing process in a method of manufacturing liquid crystal display devices, according to an embodiment of the present invention.

First, as shown in FIG. 4A, transparent substrate 1 is prepared and a metal film made of such as Cr is formed over the entire surface of substrate 1 by sputtering for example. Then, the metal film is etched selectively by photolithography technique to form gate electrode 2 together with signal lines.

Next, as shown in FIG. 4B, gate insulating film 3 made of an SiN film is formed over the entire surface of transparent substrate 1 including gate electrode 2 by plasma CVD or sputtering for example. At this moment, as film forming conditions, the film forming temperature (substrate temperature) is 380° C. and the film thickness is 300 nm. Further, an a-Si layer or an a-Si layer doped with n-type impurities is formed successively over the entire surface of gate insulating film 3 by CVD for example. Furthermore, a metal film made of such as Cr is formed over the entire surface of the a-Si layer by sputtering for example. Then, the a-Si layer and the metal film are etched simultaneously and selectively by photolithography technique to form semiconductor film 4 for a thin-film transistor (hereinafter, abbreviated as TFT) and source/drain electrode (including signal lines) 5.

Next, as shown in FIG. 4C, first insulating film 6 made of SiN is formed over the entire surface of transparent substrate 1 including source/drain electrode 5 (channel region) by such as plasma CVD and sputtering. Further, the entire surface of first insulating film 6 is applied with an SOG material having Si—O bonds, and then by baking them at 250° C. for 60 minutes in an oven for heat curing process second insulating film 7 is formed. The thickness of second insulating film 7 formed here is preferably 1.5 to 4.0 μm. A thickness of less than 1.5 μm unpreferably causes uneven parts at positions where such as TFTs are present, and furthermore at first electrode 8 and second electrode 10 formed in the following step. A thickness of more than 4.0 μm unpreferably increases the light absorption rate due to second insulating film 7 to decrease the brightness of the display area.

Further, an ITO film over the entire surface of second insulating film 7 is formed by sputtering for example. Then, the ITO film is etched selectively by photolithography technique to form first electrode 8 with a thickness of 55 nm. Here, first electrode 8 is electrically connected to the common wiring wired on the frame region of the liquid crystal display device.

Next, as shown in FIG. 4D, third insulating film 9 made of SiN, which has a favorable insulation performance, for example, is formed over the entire surface of second insulating film 7 including first electrode 8 by such as plasma CVD and sputtering. At this moment, as film forming conditions, the film forming temperature (substrate temperature) can be 230° C. to 300° C. since second insulating film 7 at the layer lower than third insulating film 9 is an SOG material with a higher heat-resisting temperature. Hence, third insulating film 9 can be formed that is more closely packed and more reliable than the case where second insulating film 2 is made of a conventional resin film.

At this moment, the gas flow ratio of mono-silane (SiH₄) to ammonia (NH₃) (both are material gases for forming a film by plasma CVD) is set to 1:6 when forming a regular bulk layer of an insulating film. Then, halfway through the process, the gas flow amount of ammonia (NH₃) is increased to make the ratio 1:16 for example. In this way, the etching rate near the surface of the insulating film is desirably higher than that at the other part (bulk layer). The film thickness of the part with the higher etching rate is desirably equal to or higher than 5% and equal to or lower than 30% (more desirably approximately equal to or higher than 8% and equal to or lower than 12%) of that of the insulating film. By thus forming a film (recess layer) with a high etching rate near the surface, contact hole 11 can be formed in a normal tapered shape.

To obtain desired moisture resistance and insulation performance of the channel region of TFTs and the source/drain electrode, the thickness of third insulating film 9 is appropriately 100 nm or more. A thickness exceeding 1,000 nm produces a lower capacitance between first electrode 8 and second electrode 10, which unpreferably prevents sufficient write voltage from being applied to the liquid crystal and requires a higher voltage for driving liquid crystal molecules.

Next, contact hole 11 for each pixel is formed by dry etching so as to collectively penetrate the three-layered insulating films (i.e. the first insulating film covering source/drain electrode 5 through the third insulating film), and part of source/drain electrode 5 is exposed once again. A mixed gas of O₂ and one of such as SF₆, CHF₃, and CF₄ as an etching gas is used for dry etching. As a result that the three layers are thus collectively etched, some manufacturing steps such as a photolithography step are eliminated and the load of an exposing step (exposure, photo-reaction process) is reduced to lower costs, compared to conventional liquid crystal display devices that are produced by patterning (forming a contact hole) by photolithography technique using a photosensitive resin material as the second insulating film.

Further, the second insulating film interposed between the first and third insulating films, both inorganic insulating films made of such as SiN, is an SOG material having Si—O bonds. Hence, uneven parts are not generated in each layer after dry etching. The selection ratio to photoresist is 2.5 or more and the etching rate is 500 nm/min or higher, and further plasma does not damage the insulating film, which allows stable patterning.

As shown in FIG. 4E, after forming contact hole 11, the entire surface of third insulating film 9 and contact hole 11 with a transparent conductive material made of ITO are coated so as to cover them. Then, second electrode (pixel electrode) 10 is formed by photolithography and etching, where the film thickness is 75 nm. In this case, part of the transparent conductive material is film-formed inside contact hole 11, which causes second electrode (pixel electrode) 10 to be electrically connected to source/drain electrode 5 (i.e. switching element).

In this embodiment, a SiN film is used as third insulating film 9; alternatively, an insulating film containing oxygen (e.g. SiO₂, SiON) as third insulating film 9 at least contacting the ITO may be used in order to reliably avoid whitish turbidness on the ITO.

The description is made of the case where first insulating film 6 is formed on source/drain electrode 5; however, first insulating film 6 is not necessarily required depending on such as the degree of reliability demanded. The present invention exhibits an advantage of increasing the retention capacity even with second insulating film 7 formed directly on source/drain electrode 5. Even with such a structure, an SOG material as second insulating film 7 provides a higher reliability than a resin material. Further, the description is made of the case where a SiN film is formed as an insulating film, but not limited to the case. A laminated film containing SiO₂, SiO, or SiN may be formed in such as a two-layer structure made from SiO₂ and SiN.

### INDUSTRIAL APPLICABILITY

The present invention is useful in that it provides a liquid crystal display device with a high aperture ratio (transmittance) at low cost.

### REFERENCE MARKS IN THE DRAWINGS

1, 12 Transparent substrate

2 Gate electrode

3 Gate insulating film

4 Semiconductor film

5 Source/drain electrode

6 First insulating film

7 Second insulating film (SOG material having Si—O bonds)

8 First electrode

9 Third insulating film

10 Second electrode

11 Contact hole

13 Liquid crystal layer

1. A liquid crystal display device comprising:
a pair of transparent substrates disposed facing each other through a liquid crystal layer;
a gate insulating film formed so as to cover a gate electrode formed in a pixel region of one of the pair of the transparent substrates closer to the liquid crystal layer;
a switching element made of a thin-film transistor placed on the gate insulating film;
a first electrode placed on the switching element through a insulating film; and
a second electrode placed on the first electrode through a insulating film,
wherein the liquid crystal display device generates an electric field in parallel with the pair of the transparent substrates and between the first and second electrodes, and
wherein the insulating film placed on the switching element is made of an SOG (spin on glass) material having Si—O bonds.

2. The liquid crystal display device according to claim 1, wherein the insulating film on the switching element and the insulating film on the first electrode have a contact hole collectively formed in the insulating films, and
wherein the second electrode is electrically connected to the switching element through the contact hole.

3. The liquid crystal display device according to claim 1, wherein the insulating film on the switching element and the insulating film on the first electrode have a contact hole collectively formed by a dry-etching method in the insulating films, and
wherein a wall surface inside the contact hole is covered with the second electrode.

4. A method of manufacturing a liquid crystal display device that include:
a pair of transparent substrates disposed facing each other through a liquid crystal layer;
a gate insulating film formed so as to cover a gate electrode formed in a pixel region of one of the pair of the transparent substrates closer to the liquid crystal layer;
a switching element made of a thin-film transistor placed on the gate insulating film;
a first electrode placed on the switching element through a insulating film; and
a second electrode placed on the first electrode through a insulating film,
the liquid crystal display device generating an electric field in parallel with the pair of the transparent substrates and between the first and second electrodes,
the method comprising the successive steps of:
forming the insulating film made of an SOG (spin on glass) material having Si—O bonds on the switching element;
then forming the first electrode on the insulating film by patterning;
then forming the insulating film on the first electrode;
then collectively forming a contact hole in a plurality of the insulating films and exposing part of the electrode of the switching element outside; and
connecting the electrode of the switching element to the second electrode.
